(19) United States
(12) Patent Application Publication
(10) Pub. No.: US 2018/0167058 A1
(43) Pub. Date: Jun. 14, 2018

(54) CLOCK GATING CELL FOR LOW SETUP TIME FOR HIGH FREQUENCY DESIGNS

(71) Applicant: QUALCOMM Incorporated, San Diego, CA (US)

(72) Inventors: Seid Hadi Rasouli, San Diego, CA (US); Xiangdong Chen, San Diego, CA (US); Venugopal Boynapalli, San Marcos, CA (US)

(21) Appl. No.: 15/372,866

(22) Filed: Dec. 8, 2016

(51) Int. Cl. H03K 3/012; H03K 5/135; H03K 3/356

(52) U.S. Cl. CPC H03K 3/012; H03K 3/356104; H03K 5/135

(57) ABSTRACT

According to certain aspects, a method for clock gating includes receiving an enable signal, and latching a logic value of the enable signal on an edge of an input clock signal. The method also includes passing the latched logic value of the enable signal to a clock-gating output when the input clock signal is logically high, blocking the latched logic value of the enable signal from the clock-gating output when the input clock signal is logically low, and pulling the clock-gating output logically low when the input clock signal is logically low.

### BACKGROUND

### Field

Aspects of the present disclosure relate generally to clock gating, and more particularly, to clock gating cells.

### Background

Reducing power consumption in a mobile device is important in order to extend the battery life of the mobile device. A significant contributor to power consumption of a chip (die) in a mobile device is dynamic power dissipation, which is due to switching of transistors on the chip. In this regard, various power reduction schemes have been developed to reduce dynamic power consumption on a chip. One scheme involves selectively gating a clock signal to a circuit block on the chip using a clock gating cell, in which the clock gating cell gates the clock signal when the circuit block is not in use. Gating the clock signal stops transistors in the circuit block from switching, thereby reducing the dynamic power dissipation of the circuit block.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

A first aspect relates to a clock gating cell. The clock gating cell includes a latch having an input and an output, wherein the latch is configured to receive an enable signal at the input of the latch, to latch a logic value of the enable signal on an edge of an input clock signal, and to output the latched logic value at the output of the latch. The clock gating cell also includes a transmission gate coupled between the output of the latch and an output of the clock gating cell, wherein the transmission gate is configured to couple the output of the latch to the output of the clock gating cell when the input clock signal is logically high, and to decouple the output of the latch from the output of the clock gating cell when the input clock signal is logically low. The clock gating cell further includes a pull-down transistor coupled between the output of the clock gating cell and a ground, wherein the pull-down transistor is configured to pull the output of the clock gating cell to the ground when the input clock signal is logically low.

A second aspect relates to a clock gating cell. The clock gating cell includes a latch having an input and an output, wherein the latch is configured to receive an enable signal at the input of the latch, to latch an inverted logic value of the enable signal on an edge of an input clock signal, and to output the latched inverted logic value of the enable signal at the output of the latch. The clock gating cell also includes a transmission gate coupled between the output of the latch and a transmission node, wherein the transmission gate is configured to couple the output of the latch to the transmission node when the input clock signal is logically high, and to decouple the output of the latch from the output of the transmission node when the input clock signal is logically low. The clock gating cell further includes an output inverter having an input coupled to the transmission node and an output coupled to an output of the clock gating cell, and a pull-up transistor coupled between the transmission node and a supply rail, wherein the pull-up transistor is configured to pull the transmission node to the supply rail when the input clock signal is logically low.

A third aspect relates to a method for clock gating. The method includes receiving an enable signal, and latching a logic value of the enable signal on an edge of an input clock signal. The method also includes passing the latched logic value of the enable signal to a clock-gating output when the input clock signal is logically high, blocking the latched logic value of the enable signal from the clock-gating output when the input clock signal is logically low, and pulling the clock-gating output logically low when the input clock signal is logically low.

A fourth aspect relates to a method for clock gating. The method includes receiving an enable signal, and latching an inverted logic value of the enable signal on an edge of an input clock signal. The method also includes passing the latched inverted logic value of the enable signal to a transmission node when the input clock signal is logically high, blocking the latched inverted logic value of the enable signal from the transmission node when the input clock signal is logically low, and pulling the transmission node logically high when the input clock signal is logically low. The method further includes inverting the latched inverted logic value of the enable signal at the transmission node.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the described embodiments are intended to include all such aspects and their equivalents.

### BRIEF DESCRIPTION OF THE DRAWINGS

FIG. 1 shows an example of a clock gating cell.

FIG. 2 shows an example of a clock gating cell according to certain aspects of the present disclosure.

FIG. 3 shows another example of a clock gating cell according to certain aspects of the present disclosure.

FIG. 4 shows still another example of a clock gating cell according to certain aspects of the present disclosure.

FIG. 5 shows an exemplary implementation of a NOR gate according to certain aspects of the present disclosure.

FIG. 6 shows an example of a system including a clock gating cell according to certain aspects of the present disclosure.

FIG. 7 shows another example of a system including a clock gating cell according to certain aspects of the present disclosure.

FIG. 8 is a flowchart illustrating an exemplary method for clock gating according to certain aspects of the present disclosure.

FIG. 9 is a flowchart illustrating another exemplary method for clock gating according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

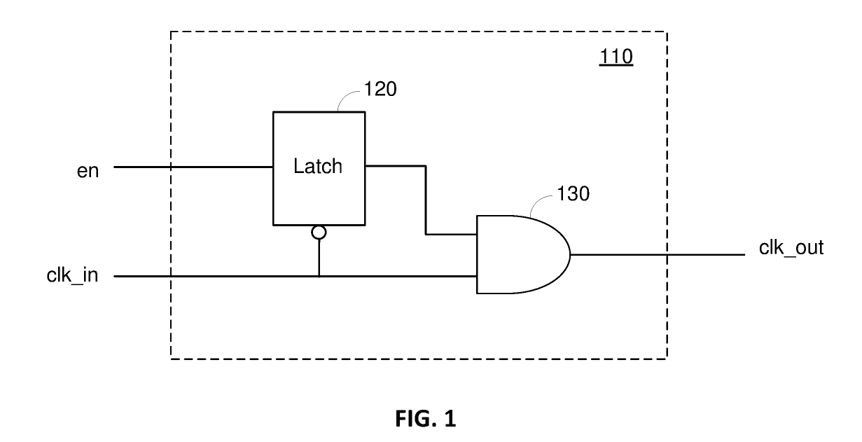

A clock gating cell (CGC) 110 typically includes a latch for latching an enable signal, and one or more logic gates for selectively gating a clock signal based on the logic value of the latched enable signal. In this regard, FIG. 1 shows an exemplary implementation of a clock gating cell (CGC) 110 for selectively gating a clock signal (denoted “clk_in”). In this example, the CGC 110 includes a negative-edge triggered latch 120 and an AND gate 130. The latch 120 has an enable input that receives an enable signal (denoted “en”), a clock input that receives the input clock signal clk_in, and an output. The AND gate 130 has a first input coupled to the output of the latch 120, a second input that receives the input clock signal clk_in, and an output that outputs the output clock signal clk_out of the CGC 110. The output of the CGC 110 may be coupled to the clock input of a circuit block (not shown).

In this example, the CGC 110 gates the clock signal clk_in when the enable signal en is low (logic zero). In this case, the CGC 110 outputs a logic zero to the circuit block regardless of the logic state of the input clock signal clk_in. The CGC 110 passes the clock signal clk_in to the circuit block when the enable signal en is high (logic one).

In operation, the latch 120 latches the logic value of the enable signal en on a falling edge of the clock signal clk_in, and outputs the latched logic value of the enable signal en to the first input of the AND gate 130. If the latched logic value of the enable signal en is logic one, then the AND gate 130 passes the clock signal clk_in to the output of the CGC 110. If the latched logic value of the enable signal en is logic zero, then the AND gate 130 outputs a logic zero regardless of the logic state of the input clock signal clk_in, effectively gating the clock signal.

A CGC has a setup time that specifies the minimum amount of time that an edge of the enable signal needs to arrive at the latch of the CGC before an edge of the input clock signal in order for the latch to properly latch the logic value of the enable signal. It is desirable for the CGC to have a low setup time. This is because a low setup time allows the edge of the enable signal to arrive at the latch of the CGC closer to the edge of the input clock signal without causing a setup time violation. This makes it easier to meet timing requirements in critical signal paths for higher clock frequencies.

In current CGC designs, when the enable signal changes from logic one to logic zero, an internal node of the latch needs to discharge to ground through a path that includes two gates in order for the latch to properly latch the logic value of zero of the enable signal. As a result, the setup time for these designs is at least two gate delays.

Embodiments of the present disclosure provide CGCs with low setup times, as discussed further below.

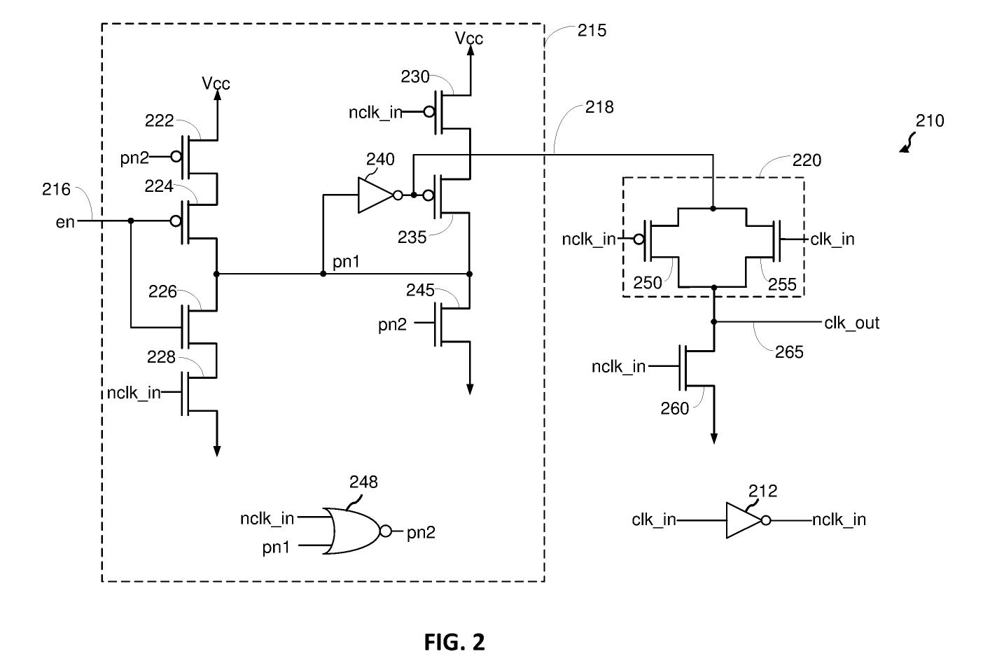

FIG. 2 shows an exemplary CGC 210 according to certain aspects of the present disclosure. The CGC 210 includes a latch 215, a transmission gate 220, and a pull-down transistor 260. The latch 215 has an enable input 216 that receives the enable signal en, and an output 218. As discussed further below, the latch 215 is configured to latch the logic value of the enable signal en on a rising edge of the input clock signal clk_in, and output the latched logic value of the enable signal en at the output 218 of the latch 215.

The transmission gate 220 is coupled between the output 218 of the latch 215 and the output 265 of the CGC 210, which provides the output clock signal clk_out to a circuit block (not shown). The pull-down transistor 260 is coupled between the output 265 of the CGC 210 and ground.

In operation, when the input clock signal clk_in is low (logic zero), the transmission gate 220 is turned off (opened) and the pull-down transistor 260 is turned on. As a result, the pull-down transistor 260 pulls the output 265 of the CGC 210 to ground (i.e., pulls the output 265 low). Thus, when the input clock signal clk_in is low (logic zero), the output clock signal clk_out is also low (logic zero).

When the input clock signal clk_in is high (logic one), the transmission gate 220 is turned on (closed) and the pull-down transistor 260 is turned off. As a result, the transmission gate 220 passes the latched logic value of the enable signal en at the output 218 of the latch 215 to the output 265 of the CGC 210. Thus, the logic value at the output 265 of the CGC 210 depends on the latched logic value of the enable signal en. If the latched logic value of the enable signal en is logic one, then the output 265 of the CGC 210 is logic one. If the latched logic value of the enable signal en is logic zero, then the output 265 of the CGC 210 is logic zero.

Thus, when the enable signal en is logic one, the output 265 of the CGC 210 is logic one when the input clock signal clk_in is logic one, and therefore tracks the input clock signal clk_in. As a result, the input clock signal clk_in is effectively passed to the output 265 of the CGC 210 in this case. When the enable signal en is logic zero, the output 265 of the CGC 210 stays at logic zero when the input clock signal clk_in is logic one, effectively gating the input clock signal clk_in. Accordingly, in this example, the input clock signal clk_in is gated when the enable signal is logic zero, and un-gated when the enable signal is logic one.

In the example in FIG. 2, the pull-down transistor 260 is implemented with an n-type metal-oxide-semiconductor (NMOS) transistor having a drain coupled to the output 265 of the CGC 210, a source coupled to ground, and a gate that receives the inverse of the input clock signal (denoted “nclk_in). The inverted clock signal nclk_in is generated by inverting the input clock signal clk_in with an inverter 212. When the input clock signal clk_in is logic zero, the inverted clock signal nclk_in is logic one. This causes the NMOS transistor to turn on, and provide a conduction path between the output 265 of the CGC 210 and ground, which pulls the output 265 to ground. When the input clock signal clk_in is logic one, the inverted clock signal nclk_in is logic zero. This causes the NMOS transistor to turn off.

In the example in FIG. 2, the transmission gate 220 is implemented with an NMOS transistor 255 and a p-type metal-oxide-semiconductor (PMOS) transistor 250 coupled in parallel between the output 218 of the latch 215 and the output 265 of the CGC 210. The gate of the NMOS transistor 255 receives the input clock signal clk_in, and the gate of the PMOS transistor 250 receives the inverted clock signal nclk_in. As discussed above, the inverted clock signal nclk_in is generated by inverter 212. When the input clock signal clk_in is logic zero (inverted clock signal nclk_in is logic one), both the NMOS transistor 255 and the PMOS transistor 250 are turned off. As a result, the output 265 of the CGC is decoupled from the output 218 of the latch 215. When the input clock signal clk_in is logic one (inverted clock signal nclk_in is logic zero), both the NMOS transistor 255 and the PMOS transistor 250 are turned on. As a result, the transmission gate 220 passes the latched logic value of the enable signal at the output 218 of the latch 215 to the output 265 of the CGC 210.

In the example in FIG. 2, the latch 215 includes PMOS transistors 222, 224, 230 and 235, NMOS transistors 226, 228 and 245, an inverter 240, and a NOR gate 248.

PMOS transistors 222 and 224 are coupled in series between the supply rail Vcc and node pn1. The gate of PMOS transistor 222 is coupled to node pn2, and the gate of PMOS transistor 224 is coupled to the enable input 216 of the latch 215. In the example shown in FIG. 2, the source of PMOS transistor 222 is coupled to the supply rail Vcc, the drain of PMOS transistor 222 is coupled to the source of PMOS transistor 224, and the drain of PMOS transistor 224 is coupled to node pn1. However, it is to be appreciated that placement of PMOS transistors 222 and 224 may be reversed.

NMOS transistors 226 and 228 are coupled in series between node pn1 and ground. The gate of NMOS transistor 226 is coupled to the enable input 216 of the latch 215, and the gate of NMOS transistor 228 is coupled to the inverted clock signal nclk_in, which is generated by inverter 212. In the example shown in FIG. 2, the drain of NMOS transistor 226 is coupled to the node pn1, the source of NMOS transistor 226 is coupled to the drain of NMOS transistor 228, and the source of NMOS transistor 228 is coupled to ground. However, it is to be appreciated that placement of NMOS transistors 226 and 228 may be reversed.

PMOS transistors 230 and 235 are coupled in series between the supply rail Vcc and node pn1. The gate of PMOS transistor 230 is coupled to the inverted clock signal nclk_in. The inverter 240 is coupled between node pn1 and the gate of PMOS transistor 235. The inverter 240 is configured to invert the logic value of node pn1, and input the inverse of the logic value of node pn1 to the gate of PMOS transistor 235. In the example in FIG. 2, the source of PMOS transistor 230 is coupled to the supply rail Vcc, the drain of PMOS transistor 230 is coupled to the source of PMOS transistor 235, and the drain of PMOS transistor 235 is coupled to node pn1.

NMOS transistor 245 is coupled between node pn1 and ground. In the example in FIG. 2, the drain of NMOS transistor 245 is coupled to node pn1, the gate of NMOS transistor 245 is coupled to node pn2, and the source of NMOS transistor 245 is coupled to ground.

The NOR gate 248 has a first input coupled to the inverted clock signal nclk_in, a second input coupled to node pn1, and an output coupled to node pn2. As discussed further below, the NOR gate 248 functions as an inverter between nodes pn1 and pn2 when the inverted clock signal nclk_in is low (input clock signal clk_in is high).

Operation of the latch 215 will now be described according to certain aspects of the present disclosure.

When the input clock signal clk_in is low (logic zero), the inverted clock signal nclk_in is high (logic one). The logic one of the inverted clock signal nclk_in causes NMOS transistor 228 to turn on. The logic one of the inverted clock signal nclk_in also causes the NOR gate 248 to output a logic zero at node pn2 regardless of the logic value at node pn1. As a result, node pn2 is low (logic zero). The logic zero at node pn2 causes PMOS transistor 222 to turn on.

Thus, when the input clock signal clk_in is low (inverted clock signal nclk_in is high), both NMOS transistor 228 and PMOS transistor 222 are turned on. PMOS transistor 222 couples the source of PMOS transistor 224 to the supply rail Vcc, and NMOS transistor 228 couples the source of NMOS transistor 226 to ground. As a result, PMOS transistor 224 and NMOS transistor 226 form an input inverter that inverts the enable signal en at the enable input 216 of the latch 215 and outputs the inverted enable signal at node pn1. Thus, when the clock signal clk_in is low, the logic value of node pn1 is the inverse of the logic value of the enable signal en.

When the input clock signal clk_in switches from low (logic zero) to high (logic one) on a rising edge of the input clock signal clk_in, the inverted clock signal nclk_in switches from high (logic one) to low (logic zero). The logic zero of the inverted clock signal nclk_in (which is input to the first input of the NOR gate 248) causes the NOR gate 248 to function as a first latch inverter that inverts the logic value of node pn1, and outputs the inverted logic value at node pn2. Thus, the logic value of node pn2 is the inverse of the logic value of node pn1.

The logic zero of the inverted clock signal nclk also causes PMOS transistors 222 and 235 and NMOS transistor 245 to form a second latch inverter that inverts the logic value of node pn2, and outputs the inverted logic value at node pn1, as explained further below. Thus, the logic value of node pn1 is the inverse of the logic value of node pn2.

Thus, when the input clock signal switch from low to high (inverted clock signal nclk_in switches from high to low), the NOR gate 248 forms a first latch inverter having an input coupled to node pn1 and an output coupled to node pn2, and PMOS transistors 222 and 235 and NMOS transistor 245 form a second latch inverter having an input coupled to node pn2 and an output coupled to node pn1. The first and second latch inverters are coupled in a closed loop, which causes the latch 215 to latch the inverted logic value of the enable signal at node pn1 on a rising edge of the input clock signal clk_in.

In the example in FIG. 2, the output 218 of the latch 215 is taken at the output of inverter 240, which inverts the latched inverted logic value of the enable signal at node pn1. Thus, the inverter 240 outputs the latched logic value of the enable signal at the output 218 of the latch 215.

The input inverter formed by PMOS transistor 224 and NMOS transistor 226 when the input clock signal clk_in is low is disabled when the input clock signal clk_in is high. This is because NMOS transistor 228 is turned off when the input clock signal clk_in is high (inverted clock signal nclk_in is low), and therefore decouples the source of NMOS transistor 226 from ground when the input clock signal clk_in is high. This closes the enable input of the latch 215, allowing the first and second latch inverters discussed above to latch the logic value of the enable signal. The input inverter is enabled when the input clock signal clk_in is low (inverted clock signal nclk_in is high) because NMOS transistor 228 is turned on in this case, and therefore couples the source of NMOS transistor 226 to ground.

The latch 215 shown in FIG. 2 has a low setup time. This is because node pn1 is only one device away from the enable input 216 of the latch 215. More particularly, when the input clock signal clk_in is low, the enable signal en only needs to propagate through the input inverter formed by PMOS 224 and NMOS 226 to reach node pn1 for latching on the rising edge of the input clock signal clk_in. The setup time of the latch 215 is lower than other designs in which an internal node of the latch needs to discharge to ground through a path that includes two gates in order to latch a logic value of zero.

As discussed above, PMOS transistors 222 and 235 and NMOS transistor 245 form the second latch inverter when the input clock signal clk_in is high (inverted clock signal nclk_in is low). An explanation of how the second latch inverter is formed will now be provided according to certain aspects of the present disclosure.

When the inverted clock signal nclk_in is low (logic zero), PMOS transistor 230 turns on and couples the source of PMOS transistor 235 to the supply rail Vcc. This causes PMOS transistor 235 and NMOS transistor 245 to form an inverter that inverts the logic value at node pn2 and outputs the inverted logic value at node pn1. Note that the gate of PMOS transistor 235 is coupled to the output of the inverter 240, which has the same logic value as node pn2. This is because the logic value at node pn2 is the inverse of the logic value at node pn1, as discussed above.

PMOS transistor 222 and NMOS transistor 245 also form an inverter depending on whether the enable signal en is high or low. When the enable signal en is low, PMOS transistor 224 is turned on, thereby coupling the drain of PMOS transistor 222 to the drain of NMOS transistor 245. In this case, PMOS transistor 222 and NMOS transistor 245 form an inverter that inverts the logic value at node pn2 and outputs the inverted logic value at node pn1. When the enable signal en is high, PMOS transistor 224 is turned off. In this case, the drain of PMOS transistor 222 is decoupled from the drain of NMOS transistor 244. In either case, PMOS transistor 235 and NMOS transistor 245 form an inverter that inverts the logic value at node pn2 and outputs the inverted logic value at node pn1, as discussed above.

Thus, the second inverter latch includes the inverter formed by PMOS transistor 235 and NMOS transistor 245 and the inverter formed by PMOS transistor 222 and NMOS transistor 245 when the enable signal en is low (logic zero), and includes the inverter formed by PMOS transistor 235 and NMOS transistor 245 when the enable signal is high (logic zero).

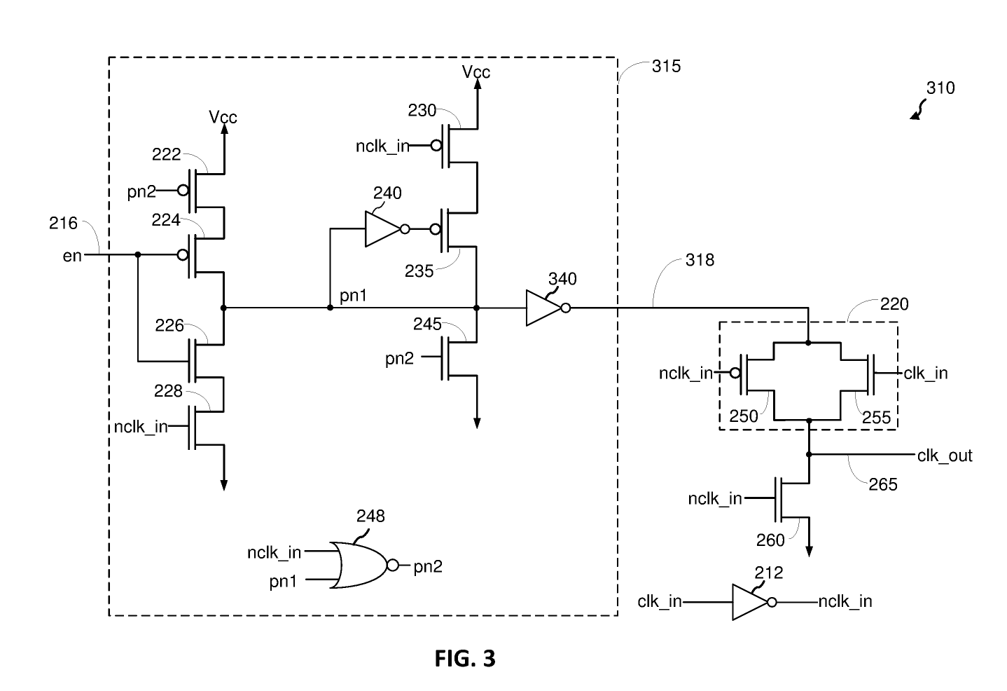

FIG. 3 shows another exemplary CGC 310 according to certain aspects of the present disclosure. The CGC 310 in this example includes the transmission gate 220 and the pull-down transistor 260 shown in FIG. 2. The CGC 310 also includes a latch 315 that is similar to the latch 215 in FIG. 2. The latch 315 in this example differs from the latch 215 in FIG. 2 in that the latch 315 also includes an output inverter 340 coupled between node pn1 and the output 318 of the latch 315. The input of the output inverter 340 is coupled to node pn1, and the output of the output inverter 340 is coupled to the output 318 of the latch 315, as shown in FIG. 3.

The output inverter 340 inverts the latched inverted logic value of the enable signal at node pn1. Thus, the output inverter 340 outputs the latched logic value of the enable signal at the output 318 of the latch 215.

The output inverter 340 may have a high current drive capability for driving a large output load (e.g., a large load coupled to the output of the CGC). Thus, in this example, the output inverter 340 helps isolate node pn1 of the latch from the output load, making the latch less sensitive to the output load.

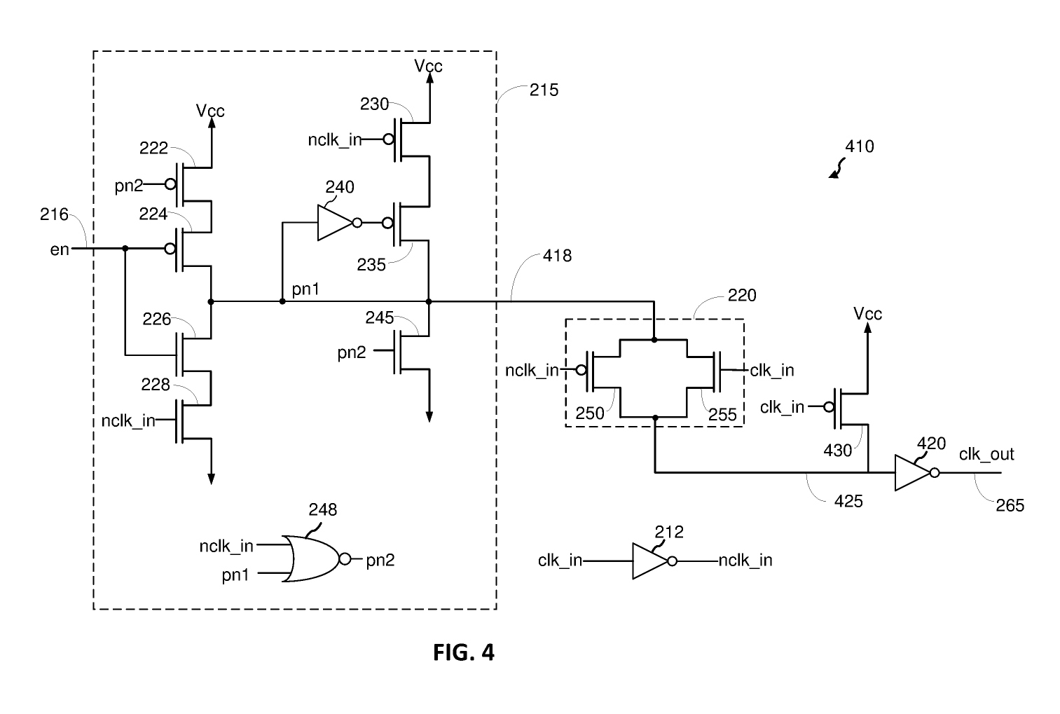

FIG. 4 shows another exemplary CGC 410 according to certain aspects of the present disclosure. The CGC 410 in this example includes the transmission gate 220 and latch 215 shown in FIG. 2. The CGC 410 differs from the CGC 210 in FIG. 2 in that the output 418 of the latch 215 is taken at node pn1 instead of the output of inverter 240. Thus, in this example, the latch 215 outputs the latched inverted logic value of the enable signal at node pn1.

The CGC 410 also differs from the CGC 210 in FIG. 2 in that the pull-down transistor 260 is replaced by a pull-up transistor 430. In addition, the CGC 410 further includes an output inverter 420 having an input coupled to the transmission gate 220 and an output coupled to the output 265 of the CGC 410.

The pull-up transistor 430 is coupled between the supply rail Vcc and a transmission node 425 of the CGC 410 (i.e., node between the transmission gate 220 and the input of the output inverter 420). The pull-up transistor 430 is configured to pull the transmission node 425 to the supply rail Vcc (i.e., pull the transmission node 425 high) when the input clock signal is low (logic zero), as discussed further below.

In operation, when the input clock signal clk_in is low (logic zero), the transmission gate 220 is turned off (opened) and the pull-up transistor 430 is turned on. As a result, the pull-up transistor 430 pulls the transmission node 425 to the supply rail Vcc (i.e., pulls the transmission node 425 high). The output inverter 420 inverts the logic value of one at the transmission node 425, and therefore outputs a logic value of zero at the output 256 of the CGC 410. Thus, when the input clock signal clk_in is low (logic zero), the output clock signal clk_out at the output 265 of the CGC 410 is also low (logic zero).

When the input clock signal clk_in is high (logic one), the transmission gate 220 is turned on (closed) and the pull-up transistor 430 is turned off. As a result, the transmission gate 220 passes the latched inverted logic value of the enable signal en at node pn1 to the input of the output inverter 420. The output inverter 420 undoes the inversion of the enable signal, and therefore output the latched logic value of the enable signal at the output 265 of the CGC 410. Thus, the logic value at the output 265 of the CGC 410 is the latched logic value of the enable signal en. If the latched logic value of the enable signal en is logic one, then the output 265 of the CGC 410 is logic one. If the latched logic value of the enable signal en is logic zero, then the output 265 of the CGC 410 is logic zero.

Thus, when the enable signal en is logic one, the output 265 of the CGC 410 is logic one when the input clock signal clk_in is logic one, and therefore tracks the input clock signal clk_in. As a result, the input clock clk_in is effectively passed to the output 265 of the CGC 410 in this case. When the enable signal en is zero, the output 265 of the CGC 410 stays at logic zero when the input clock signal clk_in is logic one, effectively gating the input clock signal clk_in. Accordingly, in this example, the input clock signal clk_in is gated when the enable signal is logic zero, and un-gated when the enable signal is logic one.

In the example in FIG. 4, the pull-up transistor 430 is implemented with a PMOS transistor having a source coupled to the supply rail Vcc, a drain coupled to the transmission node 425, and a gate that receives the input clock signal clk_in. When the input clock signal clk_in is low (logic zero), the PMOS transistor is turned on. In this case, the PMOS transistor provides a conduction path between the transmission node 425 and the supply rail Vcc, which pulls the transmission node 425 to the supply rail Vcc. When the input clock signal clk_in is high (logic one), the PMOS transistor is turned off.

In this example, the output inverter 420 may have a high current drive capability for driving a large output load (e.g., a large load coupled to the output of the CGC). This helps isolate node pn1 of the latch from the output load, making the latch less sensitive to the output load.

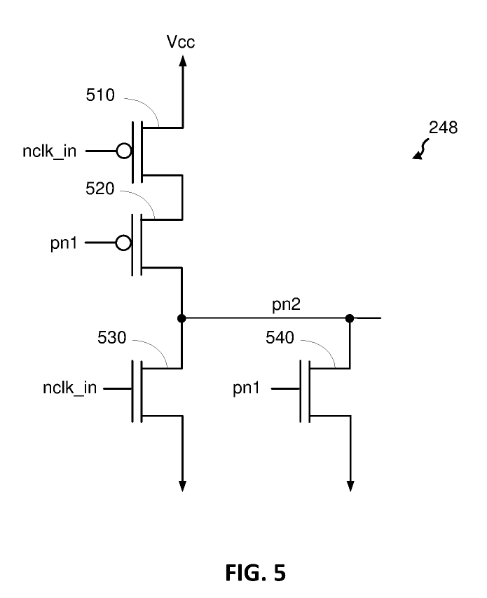

FIG. 5 shows an exemplary implementation of the NOR gate 248 according to certain aspects of the present disclosure. In this example, the NOR gate 248 includes PMOS transistors 510 and 520 and NMOS transistors 530 and 540.

PMOS transistors 510 and 520 are coupled in series between the supply rail Vcc and node pn2. The gate of PMOS transistor 510 is coupled to the inverted clock signal nclk_in, and the gate of PMOS transistor 520 is coupled to the node pn1. In the example shown in FIG. 5, the source of PMOS transistor 510 is coupled to the supply rail Vcc, the drain of PMOS transistor 510 is coupled to the source of PMOS transistor 520, and the drain of PMOS transistor 520 is coupled to node pn2. However, it is to be appreciated that placement of PMOS transistors 510 and 520 may be reversed.

NMOS transistors 530 and 540 are coupled in parallel between node pn2 and ground. The gate of NMOS transistor 530 is coupled to the inverted clock signal clk_in, and the gate of NMOS transistor 540 is coupled to node pn1. The drain of each of the NMOS transistors 530 and 540 is coupled to node pn2, and the source of each of the NMOS transistors 530 and 540 is coupled to ground.

In operation, when the inverted clock signal nclk_in is high (logic one), NMOS transistor 530 is turned on and PMOS transistor 510 is turned off. As a result, NMOS transistor 530 pulls node pn2 to ground (i.e., pulls node pn2 low). In this case, node pn2 is low (logic zero) regardless of the logic value of node pn1.

When the inverted clock signal nclk_in is low (logic zero), NMOS transistor 530 is turned off and PMOS transistor 510 is turned on. As a result, PMOS transistor 510 couples the source of PMOS transistor 520 to the supply rail Vcc. In this case, PMOS transistor 510 and NMOS transistor 540 form an inverter that inverts the logic value of node pn1, and outputs the inverted logic value at node pn2.

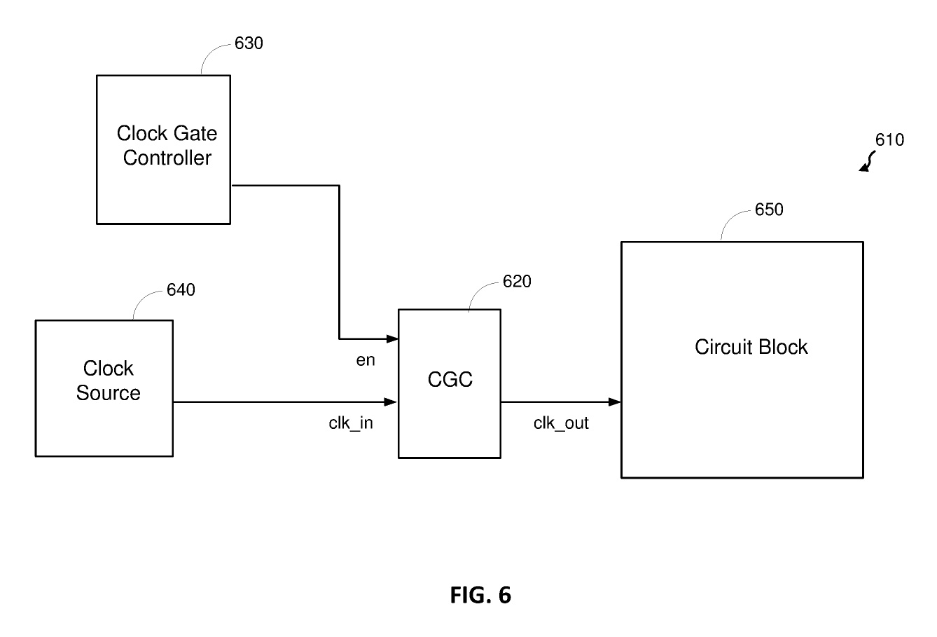

FIG. 6 shows an exemplary system 610 including a CGC 620, a clock gate controller 630, a clock source 640, and a circuit block 650. The CGC 620 may be implemented using any of the exemplary CGCs 210, 310 and 410 discussed above.

In this example, the CGC 620 receives the input clock signal clk_in from the clock source 640 via a clock path (e.g., clock path in a clock distribution network). The clock source 640 may include a phase locked loop (PLL) or another type of clock source. The CGC 620 receives the enable signal en from the clock gate controller 630. The clock gate controller 630 controls gating of the input clock signal clk_in by controlling the logic value of the enable signal en, as discussed further below. The output of the CGC 620 is coupled to the clock input of the circuit block 650. The circuit block 650 uses the output clock signal clk_out from the CGC 620 for timing operations of the circuit block 650. The circuit block 650 may include a processor, a sequential logic circuit, a pipeline, and/or one or more flip-flops, etc.

In operation, the clock gate controller 630 may monitor an activity state of the circuit block 650, and determine whether to gate the clock signal clk_in based on the monitored state. For example, if the circuit block 650 is in an inactive state (e.g., not processing data, not receiving data, etc.), then the clock gate controller 630 may gate the clock signal clk_in by asserting the enable signal en to the CGC 620 low (logic zero). The inactive state may also be referred to as an idle state. If the circuit block 650 is in an active state (e.g., processing data, receiving data, etc.), then the clock gate controller 630 may un-gate the clock signal clk_in by asserting the enable signal en to the CGC 620 high (logic one).

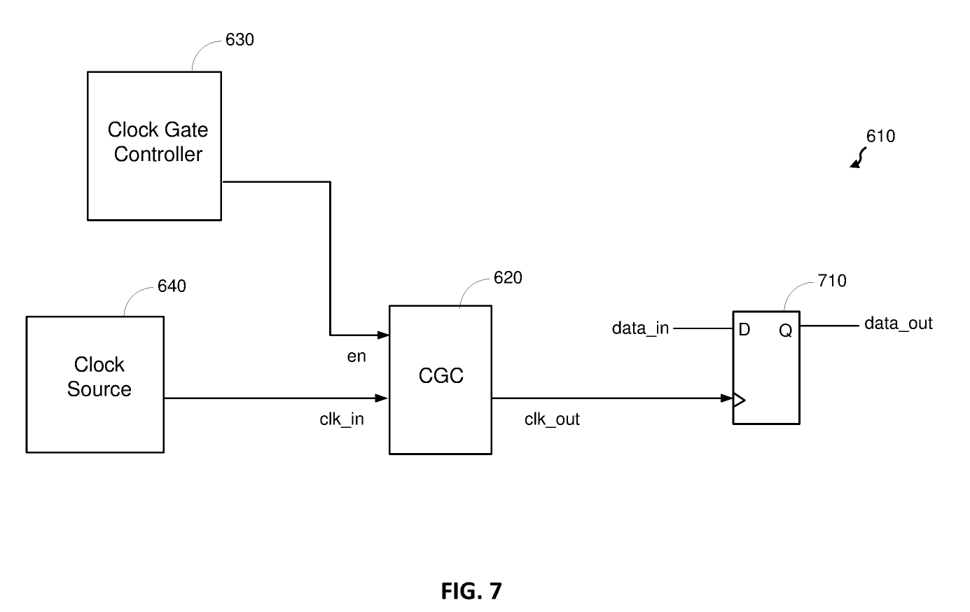

FIG. 7 shows an example in which the circuit block 650 in FIG. 6 includes one or more flip flops 710. For simplicity, only one flip flop is shown in FIG. 7. In this example, the flop-flop 710 has a clock input that receives the clock signal clk_out from the CGC 620, a data input D that receives an input data signal (denoted “data_in), and an output Q. In operation, the flip flop 710 latches (captures) a logic value of the input data signal on an active edge of the clock signal clk_out, and outputs the latched logic value at the output Q. The active edge may be a rising edge or a falling edge depending on whether the flip flop is positive-edge triggered or negative-edge triggered. More particularly, if the flip flop 710 is a positive-edge triggered flip flop, then the flip flop 710 latches the logic value of the data signal on a rising edge of the clock signal clk_out. If the flip flop 710 is a negative-edge edge triggered flip flop, then the flip flop 710 latches the logic value of the data signal on a falling edge of the clock signal clk_out.

In this example, the clock gate controller 630 may monitor the input D and/or output Q of the flip flop 710 to determine whether to gate the clock signal clk_in. For example, if the logic values at the input D and output Q of the flip flop 710 are the same over one or more clock cycles (e.g., of the input clock signal clk_in), then the clock gate controller 630 may determine to gate the clock signal to the flip flop 710 to conserve power. This may occur when the flip flop 710 is not receiving new data that needs to be latched. In this case, clock gate controller 630 may gate the clock signal clk_in by asserting the enable signal en to the CGC 620 low (logic zero). If the logic values at the input D and output Q of the flip flop 710 are different, then the clock gate controller 630 may determine to un-gate the clock signal. In this case, the gate clock gate controller 630 may un-gate the clock signal clk_in by asserting the enable signal en to the CGC 620 high (logic one).

The flip flop 710 may be used, for example, to latch data in a sequential logic circuit, a pipeline, a processor, a shift register, etc. The flip flop 710 may also be used to synchronize a data signal with the clock signal clk_out by latching logic values of the data signal on rising or falling edges of the clock signal clk_out.

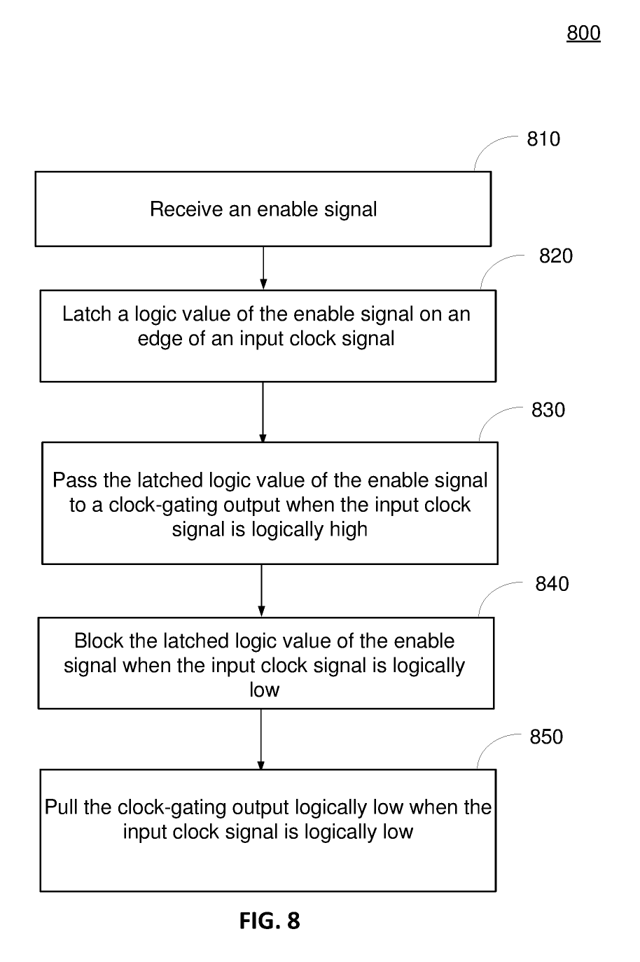

FIG. 8 is a flowchart illustrating a method 800 for clock gating according to certain aspects. The method 800 may be performed by CGC 210 or 310.

At step 810, an enable signal is received. For example, the enable signal may be received from a clock gate controller (e.g., clock gate controller 630).

At step 820, a logic value of the enable signal is latched on an edge of an input clock signal. For example, the logic value may be latched on a rising edge of the input clock signal (e.g., input clock signal clk_in).

At step 830, the latched logic value of the enable signal is passed to a clock-gating output when the input clock signal is logically high. For example, the latched logic value may be passed to the clock-gating output (e.g., output 265) by turning on a transmission gate (e.g., transmission gate 220).

At step 840, the latched logic value of the enable signal is blocked from the clock-gating output when the input clock signal is logically low. For example, the latched logic value may be blocked by turning off the transmission gate.

At step 850, the clock-gating output is pulled logically low when the input clock signal is logically low. For example, the output may be pulled low (e.g., to ground) by turning on a pull-down transistor (e.g., pull-down transistor 260).

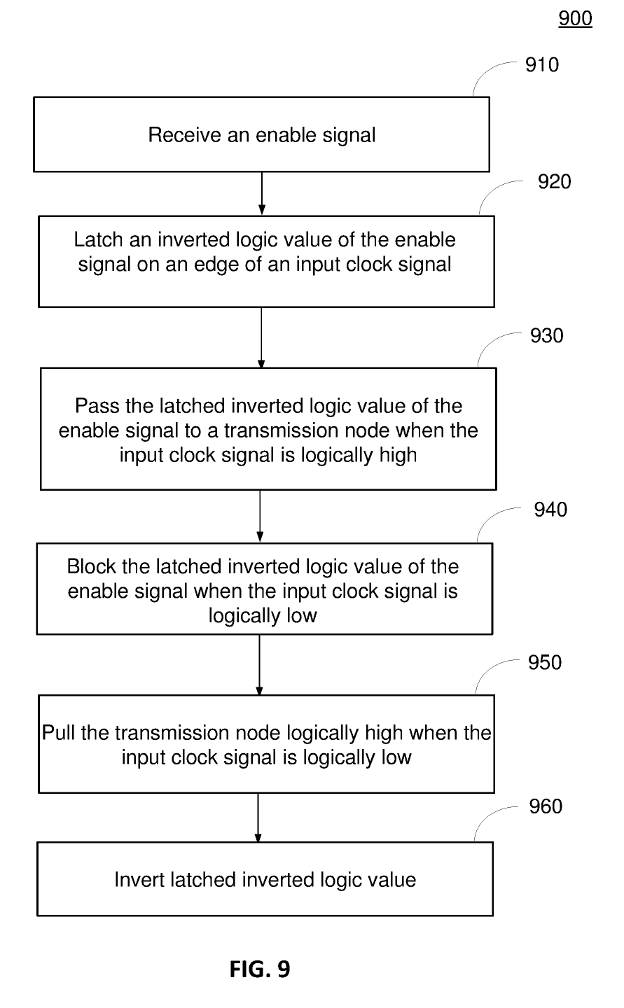

FIG. 9 is a flowchart illustrating a method 900 for clock gating according to certain aspects. The method 900 may be performed by CGC 410.

At step 910, an enable signal is received. For example, the enable signal may be received from a clock gate controller (e.g., clock gate controller 630).

At step 920, an inverted logic value of the enable signal is latched on an edge of an input clock signal. For example, the inverted logic value may be latched on a rising edge of the input clock signal (e.g., input clock signal clk_in).

At step 930, the latched inverted logic value of the enable signal is passed to a transmission node when the input clock signal is logically high. For example, the latched inverted logic value may be passed to the transmission node (e.g., transmission node 425) by turning on a transmission gate (e.g., transmission gate 220).

At step 940, the latched inverted logic value of the enable signal is blocked from the transmission node when the input clock signal is logically low. For example, the latched inverted logic value may be blocked by turning off the transmission gate.

At step 950, the transmission node is pulled logically high when the input clock signal is logically low. For example, the transmission node may be pulled high (e.g., to supply rail Vcc) by turning on a pull-up transistor (e.g., pull-up transistor 430).

At step 960, the latched inverted logic value of the enable signal is inverted. For example, the latched inverted logic value may be inverted using an inverter (e.g., output inverter 420). The resulting inverted latched inverted logic value may be output to the clock input of a circuit block (e.g., circuit block 650).

It is to be appreciated that the present disclosure is not limited to the exemplary terminology used above. For example, a transmission gate may also be referred to as a switch, a pass gate, or another term. Also, a CGC may be referred to as a clock gating circuit or another term.

In the present disclosure, the term “logically low” corresponds to a logic value of zero, and the term “logically high” corresponds to a logic value of one. A logic value of zero may correspond to a voltage approximately equal to ground, and a logic value of one may correspond to a voltage approximately equal to the supply voltage of the supply rail Vcc.

The clock gate controller 630 discussed above may be implemented with a general-purpose processor, a digital signal processor (DSP), an application specific integrated circuit (ASIC), a field programmable gate array (FPGA) or other programmable logic device, discrete hardware components (e.g., logic gates), or any combination thereof designed to perform the functions described herein. A processor may perform the functions described herein by executing software comprising code for performing the functions. The software may be stored on a computer-readable storage medium, such as a RAM, a ROM, an EEPROM, an optical disk, and/or a magnetic disk.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A clock gating cell, comprising:
a latch having an input and an output, wherein the latch is configured to receive an enable signal at the input of the latch, to latch a logic value of the enable signal on an edge of an input clock signal, and to output the latched logic value at the output of the latch;
a transmission gate coupled between the output of the latch and an output of the clock gating cell, wherein the transmission gate is configured to couple the output of the latch to the output of the clock gating cell when the input clock signal is logically high, and to decouple the output of the latch from the output of the clock gating cell when the input clock signal is logically low; and
a pull-down transistor coupled between the output of the clock gating cell and a ground, wherein the pull-down transistor is configured to pull the output of the clock gating cell to the ground when the input clock signal is logically low.

2. The clock gating cell of claim 1, wherein the pull-down transistor comprises an n-type metal-oxide-semiconductor (NMOS) transistor having a drain coupled to the output of the clock gating cell, a source coupled to the ground, and a gate coupled to an inverse of the input clock signal.

3. The clock gating cell of claim 1, wherein the transmission gate comprises an n-type metal-oxide-semiconductor (NMOS) transistor and a p-type metal-oxide-semiconductor (PMOS) transistor coupled in parallel, the NMOS transistor has a gate coupled to the input clock signal, and the PMOS transistor has a gate coupled to an inverse of the input clock signal.

4. The clock gating cell of claim 1, wherein the latch comprises:
a NOR gate having a first input coupled to a first node of the latch, a second input coupled to an inverse of the input clock signal, and an output coupled to a second node of the latch; and
a latch inverter having an input coupled to the second node of the latch, and an output coupled to the first node of the latch.

5. The clock gating cell of claim 4, wherein the latch further comprises an input inverter having an input coupled to the input of the latch and an output coupled to the first node of the latch, wherein the input inverter is enabled when the input clock signal is logically low, and the input inverter is disabled when the input clock signal is logically high.

6. The clock gating cell of claim 4, further comprising:
a first p-type metal-oxide-semiconductor (PMOS) transistor;
a second PMOS transistor, wherein the first and second PMOS transistors are coupled in series between a supply rail and the first node of the latch, the first PMOS transistor has a gate coupled to the output of the NOR gate, and the second PMOS transistor has a gate coupled to the input of the latch;
a first n-type metal-oxide-semiconductor (NMOS) transistor; and
a second NMOS transistor, wherein the first and second NMOS transistors are coupled in series between the first node and the ground, the first NMOS transistor has a gate coupled to the input of the latch, and the second NMOS transistor has a gate coupled to the inverse of the input clock signal.

7. The clock gating cell of claim 1, wherein the output of the clock gating cell is coupled to a clock input of a flip flop.

8. A clock gating cell, comprising:
a latch having an input and an output, wherein the latch is configured to receive an enable signal at the input of the latch, to latch an inverted logic value of the enable signal on an edge of an input clock signal, and to output the latched inverted logic value of the enable signal at the output of the latch;
a transmission gate coupled between the output of the latch and a transmission node, wherein the transmission gate is configured to couple the output of the latch to the transmission node when the input clock signal is logically high, and to decouple the output of the latch from the output of the transmission node when the input clock signal is logically low;
an output inverter having an input coupled to the transmission node and an output coupled to an output of the clock gating cell; and
a pull-up transistor coupled between the transmission node and a supply rail, wherein the pull-up transistor is configured to pull the transmission node to the supply rail when the input clock signal is logically low.

9. The clock gating cell of claim 8, wherein the pull-up transistor comprises an p-type metal-oxide-semiconductor (PMOS) transistor having a source coupled to the supply rail, a drain coupled to the transmission node, and a gate coupled to the input clock signal.

10. The clock gating cell of claim 8, wherein the transmission gate comprises an n-type metal-oxide-semiconductor (NMOS) transistor and a p-type metal-oxide-semiconductor (PMOS) transistor coupled in parallel, the NMOS transistor has a gate coupled to the input clock signal, and the PMOS transistor has a gate coupled to an inverse of the input clock signal.

11. The clock gating cell of claim 8, wherein the latch comprises:
a NOR gate having a first input coupled to a first node of the latch, a second input coupled to an inverse of the input clock signal, and an output coupled to a second node of the latch; and
a latch inverter having an input coupled to the second node of the latch, and an output coupled to the first node of the latch.

12. The clock gating cell of claim 11, wherein the latch further comprises an input inverter having an input coupled to the input of the latch and an output coupled to the first node of the latch, wherein the input inverter is enabled when the input clock signal is logically low, and the input inverter is disabled when the input clock signal is logically high.

13. The clock gating cell of claim 11, further comprising:
a first p-type metal-oxide-semiconductor (PMOS) transistor;
a second PMOS transistor, wherein the first and second PMOS transistors are coupled in series between a supply rail and the first node of the latch, the first PMOS transistor has a gate coupled to the output of the NOR gate, and the second PMOS transistor has a gate coupled to the input of the latch;
a first n-type metal-oxide-semiconductor (NMOS) transistor; and
a second NMOS transistor, wherein the first and second NMOS transistors are coupled in series between the first node and the ground, the first NMOS transistor has a gate coupled to the input of the latch, and the second NMOS transistor has a gate coupled to the inverse of the input clock signal.

14. The clock gating cell of claim 8, wherein the output of the clock gating cell is coupled to a clock input of a flip flop.

15. A method for clock gating, comprising:
receiving an enable signal;
latching a logic value of the enable signal on an edge of an input clock signal;
passing the latched logic value of the enable signal to a clock-gating output when the input clock signal is logically high;
blocking the latched logic value of the enable signal from the clock-gating output when the input clock signal is logically low; and
pulling the clock-gating output logically low when the input clock signal is logically low.

16. The method of claim 15, wherein the clock-gating output is coupled to a clock input of a flip flop.

17. The method of claim 15, wherein the edge of the input clock signal is a rising edge of the input clock signal.

18. A method for clock gating, comprising:
receiving an enable signal;
latching an inverted logic value of the enable signal on an edge of an input clock signal;
passing the latched inverted logic value of the enable signal to a transmission node when the input clock signal is logically high;
blocking the latched inverted logic value of the enable signal from the transmission node when the input clock signal is logically low;
pulling the transmission node logically high when the input clock signal is logically low; and
inverting the latched inverted logic value of the enable signal at the transmission node.

19. The method of claim 18, further comprising outputting the inverted latched inverted logic value to a clock input of a flip flop.

20. The method of claim 18, wherein the edge of the input clock signal is a rising edge of the input clock signal.
